(19) United States
(12) Patent Application Publication
(10) Pub. No.: US 2019/0043567 A1
(43) Pub. Date: Feb. 7, 2019

(54) TEMPERATURE-DEPENDENT READ OPERATION TIME ADJUSTMENT IN NON-VOLATILE MEMORY DEVICES

(71) Applicant: Intel Corporation, Santa Clara, CA (US)

(72) Inventors: Ali Khakifirooz, Los Altos, CA (US); Shantanu Rajwade, Santa Clara, CA (US); Rohit Shenoy, Fremont, CA (US); Aliasgar Madraswala, Folsom, CA (US); Pranav Kalavade, San Jose, CA (US)

(21) Appl. No.: 16/115,372

(22) Filed: Aug. 28, 2018

(51) Int. Cl. G11C 11/56; G11C 16/26; H01L 23/00; G06F 3/06

(52) U.S. Cl. CPC G11C 11/5642; G11C 11/5671; G11C 16/26; G11C 16/0483; G06F 3/0604; G06F 3/0659; G06F 3/0679; H01L 24/16

(57) ABSTRACT

An apparatus and/or system is described including a memory device or a controller for a memory device to perform an adjustment of a read operation time for data stored in the memory device. In embodiments, the apparatus may receive a request for data stored in the memory device and a read operation time adjustment module operable by the controller may acquire a first operation temperature of the memory device, obtained at a time of programming of the data stored in the memory device. The apparatus may acquire a second operation temperature of the memory device, obtained after the request for the data stored in the memory device is received. Based at least partially on the first operation temperature and the second operation temperature, the apparatus may adjust the read operation time to read the data. Other embodiments are disclosed and claimed.

### FIELD

Embodiments of the present disclosure generally relate to the field of integrated circuits (IC), and more particularly, to non-volatile memory devices.

### BACKGROUND

In order to correctly read data stored in a non-volatile memory device, such as, e.g., a multi-level cell (MLC) NAND memory device, the memory device is typically designed to have enough read window budget (RWB) to account for stringent or other varying working conditions. The RWB is a voltage window that includes the difference between the read voltage level and an edge of a threshold voltage distribution being discriminated during a read operation. Many factors cause challenging working conditions associated with programming and read operations. Such factors include, for example, program and read noise, temperature variations, cycling effects, program and read disturb mechanisms, as well as memory cell to memory cell, wordline to wordline, block to block, and die to die variations. Under less stringent conditions, such as, for example when a temperature variation is less than an entire allowed working temperature, excess RWB is often left unused.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example and not by way of limitation in the figures of the accompanying drawings.

FIG. 1 illustrates an example die in which a memory device may be provided, in accordance with embodiments of the present disclosure.

FIG. 2 schematically illustrates a cross-section side view of an integrated circuit (IC) assembly that may include a memory device, in accordance with embodiments of the present disclosure.

FIG. 3 includes a schematic representation of an example threshold voltage distribution of a multi-level memory cell and accompanying table corresponding to the threshold voltage distribution, in accordance with embodiments of the present disclosure.

FIG. 4 is an example waveform of a selected wordline illustrating a read operation for a page of data, in accordance with embodiments of the present disclosure.

FIGS. 5 and 6 are flow diagrams illustrating respective example processes, in accordance with embodiments of the present disclosure.

FIG. 7 is a flow diagram illustrating an example process, in accordance with embodiments of the present disclosure.

FIGS. 8A and 8B are example waveforms of a selected wordline illustrating read operations for reading a page of data, in accordance with embodiments of the present disclosure.

FIG. 9 a schematic of a computing system, in accordance with embodiments of the present disclosure.

### DETAILED DESCRIPTION

In embodiments, a memory device or apparatus coupled to the memory device performs operations associated with a read operation time adjustment based at least in part on a program operation temperature (also referred to as “operating temperature,” but hereinafter referred to as “operation temperature”) and a read operation temperature of the memory device. For example, a controller or other component associated with the memory device obtains and stores a program operation temperature at a time of programming of data into the memory device. In embodiments, after receiving a request for the data, the controller acquires the stored program operation temperature of the memory device by retrieving it and subsequently acquires a read operation temperature of the memory device. Based on the program operation temperature and the read operation temperature, in embodiments, the apparatus adjusts a read operation time for the memory device. In embodiments, the apparatus adjusts the read operation time for the data by increasing or decreasing a stabilization wait time prior to a sense operation to be performed during the read operation.

In the following description, various aspects of the illustrative implementations will be described using terms commonly employed by those skilled in the art to convey the substance of their work to others skilled in the art. However, it will be apparent to those skilled in the art that embodiments of the present disclosure may be practiced with only some of the described aspects. For purposes of explanation, specific numbers, materials and configurations are set forth in order to provide a thorough understanding of the illustrative implementations. However, it will be apparent to one skilled in the art that embodiments of the present disclosure may be practiced without the specific details. In other instances, well-known features are omitted or simplified in order not to obscure the illustrative implementations.

In the following detailed description, reference is made to the accompanying drawings that form a part hereof, wherein like numerals designate like parts throughout, and in which is shown by way of illustration embodiments in which the subject matter of the present disclosure may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

In some cases, various operations will be described as multiple discrete operations in turn, in a manner that is most helpful in understanding the present disclosure; however, the order of description should not be construed to imply that these operations are necessarily order dependent. In particular, these operations need not be performed in the order of presentation.

For the purposes of the present disclosure, the phrase “A and/or B” means (A), (B), (A) or (B), or (A and B). For the purposes of the present disclosure, the phrase “A, B, and/or C” means (A), (B), (C), (A and B), (A and C), (B and C), or (A, B and C).

The description may use perspective-based descriptions such as top/bottom, in/out, over/under, and the like. Such descriptions are merely used to facilitate the discussion and are not intended to restrict the application of embodiments described herein to any particular orientation.

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. Furthermore, it is to be understood that the various embodiments shown in the Figures (“FIGs.”) are illustrative representations and are not necessarily drawn to scale.

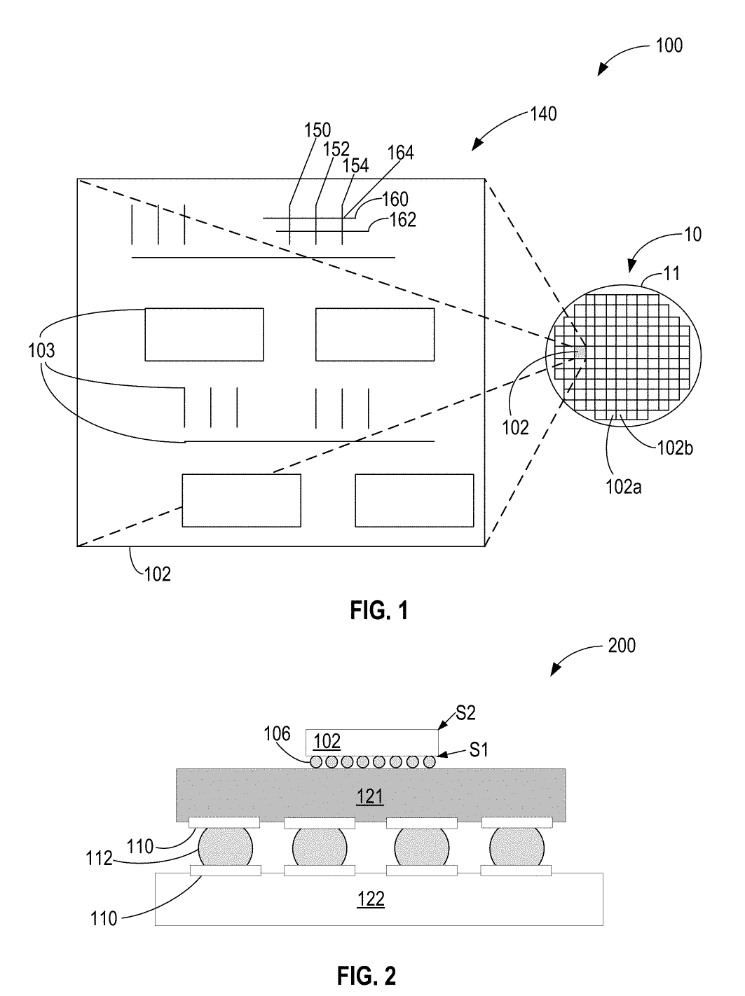

FIG. 1 illustrates an example die in which a memory device may be provided using the techniques of the present disclosure, in accordance with some embodiments. More specifically, FIG. 1 schematically illustrates a top view of die 102 in wafer form 10 and in singulated form 140, in accordance with some embodiments. In some embodiments, the die 102 may be one of a plurality of dies (e.g., die 102, 102a, 102b) of a wafer 11 composed of semiconductor material such as, for example, silicon or other suitable material. The plurality of dies may be formed on a surface of the wafer 11. Each of the dies may be a repeating unit of a semiconductor product that may include a memory device. For example, die 102 may include circuitry 103 and/or another memory device module or component as described herein to perform a read operation time adjustment based at least in part on a program operation temperature and a read operation temperature of the memory device as described herein in accordance with some embodiments. According to various embodiments, the circuitry 103 may include one or more memory elements (memory cells, such as, e.g., multi-level per cell memory cells), which may be configured in an array, such as a two-dimensional (2D) or three-dimensional (3D) non-volatile multi-level cell (MLC) memory array. In some embodiments, the memory array may comprise a 3D multi-level per cell such as three-level-per-cell (TLC) or four-level-per-cell (QLC) NAND memory array. In some embodiments, the memory array may comprise a cross-point MLC memory array.

The circuitry 103 may further include one or more wordline(s) (also referred to as “WL” or “WLs”) (e.g., 150, 152, 154) and one or more bitline(s) (also referred to as “BL” or “BLs”) (e.g., 160, 162) coupled to the memory elements. Only three wordlines and two bitlines are shown in FIG. 1 for ease of understanding. In some embodiments, the bitlines and wordlines may be configured such that each of the memory elements may be disposed at an intersection (e.g., 164) of each individual bitline and wordline (e.g., 160 and 154), in a cross-point configuration. A voltage or bias can be applied to a target memory element of the memory elements using the wordlines and the bitlines to select the target memory cell for a read or write operation. Bitline drivers may be coupled to the bitlines and wordline drivers may be coupled to the wordlines to facilitate decoding/selection of the memory elements. To enable memory cell selection, the wordlines 150, 152, 154 may be connected with memory cells and other parts of circuitry 103 via interconnects, including respective contact structures (e.g., vias) that provide electrical connectivity through the layers of the die 102 as described below in greater detail. It is noted that the circuitry 103 is only schematically depicted in FIG. 1 and may represent a wide variety of suitable logic or memory in the form of circuitry or other suitable devices and configurations including, for example, one or more state machines including circuitry and/or instructions in storage (e.g., firmware or software) configured to perform actions such as read, program, verify and/or analysis operations in connection with a read operation time adjustment as described herein.

In some embodiments, circuitry 103 may be formed using suitable semiconductor fabrication techniques, some of which are described herein. After a fabrication process of the semiconductor product is complete, the wafer 11 may undergo a singulation process in which each of the dies (e.g., die 102) may be separated from one another to provide discrete “chips” of the semiconductor product. The wafer 11 may be any of a variety of sizes. According to various embodiments, the circuitry 103 may be disposed on a semiconductor substrate in wafer form 10 or singulated form 140. In some embodiments, the die 102 may include logic or memory, or combinations thereof.

FIG. 2 schematically illustrates a cross-section side view of an integrated circuit (IC) assembly 200 that may include a memory device provided in accordance with some embodiments described herein. In some embodiments, the IC assembly 200 may include one or more dies electrically and/or physically coupled with a package substrate 121. The die 102 may include circuitry (e.g., circuitry 103 of FIG. 1) and/or other suitable components or modules to perform operations in connection with a read operation time adjustment as described herein. In some embodiments, the package substrate 121 is coupled with a circuit board 122, as shown.

The IC assembly 200 may include a wide variety of configurations including, for example, suitable combinations of flip-chip and/or wire-bonding configurations, interposers, multi-chip package configurations including System in Package (SiP) and/or Package on Package (PoP) configurations. For example, the die 102 can be attached to the package substrate 121 according to a wide variety of suitable configurations including, for example, being directly coupled with the package substrate 121 in a flip-chip configuration, as depicted. In the flip-chip configuration, an active side, S1, of the die 102 including active circuitry is attached to a surface of the package substrate 121 using die-level interconnect structures 106 such as bumps, pillars, or other suitable structures that may also electrically couple the die 102 with the package substrate 121. The active side S1 of the die 102 may include circuitry such as, for example, memory elements as described in reference to FIG. 1. An inactive side, S2, may be disposed opposite to the active side S1, as can be seen. In other embodiments, the die 102 may be disposed on another die that is coupled with the package substrate 121 in any of a variety of suitable stacked die configurations. For example, a processor die may be coupled with the package substrate 121 in a flip-chip configuration and the die 102 may be mounted on the processor die in a flip-chip configuration and electrically coupled with the package substrate 121 using through-silicon vias (TSVs) formed through the processor die. In still other embodiments, the die 102 may be embedded in the package substrate 121 or coupled with a die that is embedded in the package substrate 121. Other dies may be coupled with the package substrate 121 in a side-by-side configuration with the die 102 in other embodiments.

In some embodiments, the die-level interconnect structures 106 may be configured to route electrical signals between the die 102 and the package substrate 121. The electrical signals may include, for example, input/output (I/O) signals and/or power/ground signals that are used in connection with operation of the die. The die-level interconnect structures 106 may be coupled with corresponding die contacts disposed on the active side S1 of the die 102 and corresponding package contacts disposed on the package substrate 121. The die contacts and/or package contacts may include, for example, pads, vias, trenches, traces and/or other suitable contact structures, fabrication of some of which is described below.

In some embodiments, the package substrate 121 may comprise an epoxy-based laminate substrate having a core and/or build-up layers such as, for example, an Ajinomoto Build-up Film (ABF) substrate. The package substrate 121 may include other suitable types of substrates in other embodiments including, for example, substrates formed from glass, ceramic, or semiconductor materials.

The package substrate 121 may include electrical routing features configured to route electrical signals to or from the die 102. The electrical routing features may include, for example, package contacts (e.g., pads 110) disposed on one or more surfaces of the package substrate 121 and/or internal routing features (not shown) such as, for example, trenches, vias or other interconnect structures to route electrical signals through the package substrate 121.

In some embodiments, the package substrate 121 may be coupled with a circuit board 122, as can be seen. The circuit board 122 may be a printed circuit board (PCB) composed of an electrically insulative material such as an epoxy laminate. For example, the circuit board 122 may include electrically insulating layers composed of materials that may be laminated together. Interconnect structures (not shown) such as traces, trenches, or vias may be formed through the electrically insulating layers to route the electrical signals of the die 102 through the circuit board 122. The circuit board 122 may be composed of other suitable materials in other embodiments. In some embodiments, the circuit board 122 may be a motherboard and may be included in a computing device, such as, for example, a mobile device.

Package-level interconnects such as, for example, solder balls 112 may be coupled to pads 110 on the package substrate 121 and/or on the circuit board 122 to form corresponding solder joints that may be configured to further route the electrical signals between the package substrate 121 and the circuit board 122. The pads 110 may be composed of any suitable electrically conductive material such as metal. The package-level interconnect may include other structures and/or configurations including, for example, land-grid array (LGA) structures and the like. In embodiments, the die 102 of the IC assembly 200 may be, include, or be a part of an IC including a memory device, such as, e.g., a multi-level cell (MLC) non-volatile memory device as described herein.

An important factor that determines a read window budget (RWB) of a memory device is an operation temperature of the memory device. For example, to perform correctly, a memory device, e.g., a non-volatile memory (NVM) device, may need to function over a temperature range of 0° C.-85° C. Typically, if a memory cell of the memory device is programmed with data at a first temperature and then read at a second, e.g., higher, temperature, its threshold voltage level (“threshold voltage”) may appear lower than its actual threshold voltage. If, however, the memory cell is read at a lower temperature than when the memory cell was programmed, its threshold voltage may appear higher than its actual threshold voltage. Temperature dependence of memory cells may vary based upon a memory cell's threshold voltage as well as its location within the memory device. Thus, various methods of compensating for a memory device temperature to correctly read data, such as, e.g., a controller or memory device's adjustment of read voltage levels, may not fully compensate for a temperature dependence of a memory cell.

Accordingly, in embodiments, during program operation of a memory device, e.g., non-volatile memory (NVM) device, a component of the memory device or controller may obtain a first operation temperature and store it with data to be stored in the NVM device. In embodiments, during a read operation, the controller may acquire or retrieve the first operation temperature. The controller may then acquire a second operation temperature corresponding to a time of the read operation. Based on the first operation temperature and the second operation temperature, the controller may increase or decrease a read operation time of the data.

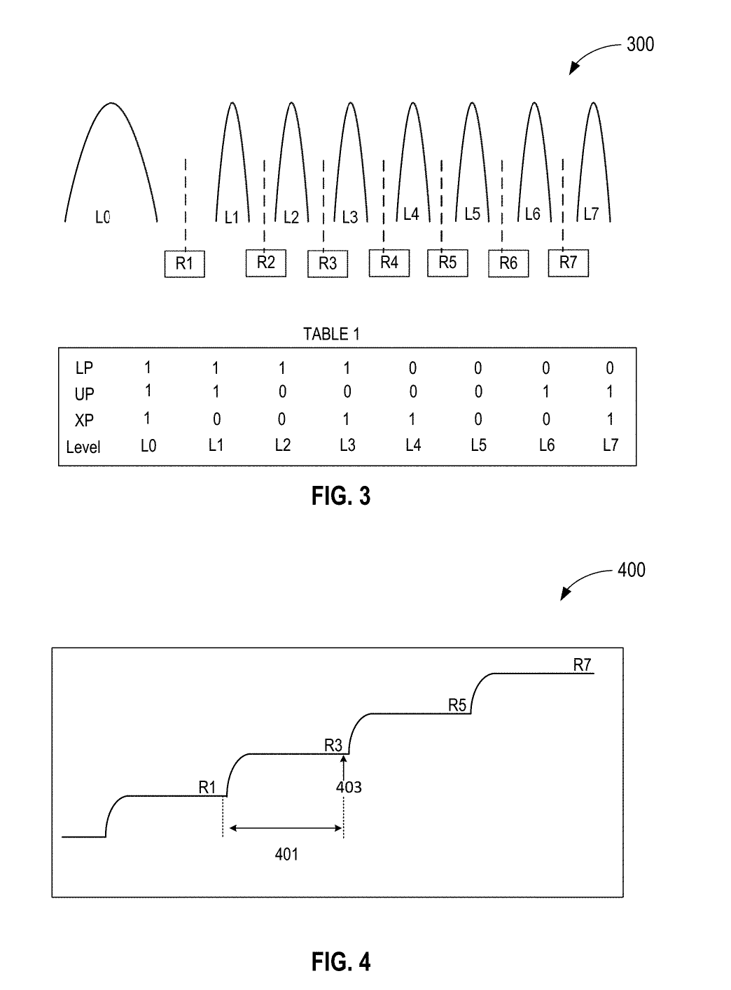

In a multi-level cell (MLC) non-volatile memory device, e.g., an MLC NAND memory device, a memory cell stores more than one bit of data. Each of a plurality of bits in a single memory cell may be separately mapped to logical units, called a page, generally the smallest unit for program and read operations in the MLC NAND memory device. For example, in a three-level per cell or triple-level per cell (TLC) NAND memory array, a memory cell is programmed to store 3 bits of data. To illustrate, FIG. 3 includes a schematic representation of a threshold voltage distribution 300 of memory cells of an example TLC NAND memory array, in embodiments. In threshold voltage distribution 300, voltage extends horizontally and a population of memory cells extends vertically. In embodiments, during program operation, three pages of data—a lower page, upper page, and extra page (also referred to as LP, UP, and XP)—are provided. Memory cells that belong to a selected wordline (WL) are programmed to at least one of the eight possible threshold voltage levels, e.g., denoted by L0 . . . L7, in the example of FIG. 3. In embodiments, corresponding Table 1 includes an example of a Gray code to encode each of three bits of data into one of the eight threshold voltage levels stored in the example TLC memory cell. Note that Table 1 is simply an example, and any suitable code or coding method may be contemplated.

Accordingly, in embodiments, a component associated with the memory device, e.g., a controller, performs a read operation by comparing a threshold voltage of memory cells of a selected WL against reference read voltage levels (also, “read voltages”), e.g., R1-R7, of threshold voltage distribution 300. For example, to read data of a lower page (LP), the controller compares a threshold voltage of a memory cell against read voltage level R4, located between threshold voltage levels L3 and L4, in FIG. 3. Similarly, to read data of an upper page (UP), the controller compares a threshold voltage of the memory cell against read voltage levels R2 and R6. In embodiments, to read the data of an extra page (XP), the controller compares a threshold voltage of the memory cell against read voltage levels R1, R3, R5, and R7. Accordingly, in embodiments, to perform the comparisons, the controller performs a plurality of sense operations by applying a series of read voltages, Rᵢ, corresponding to one or more corresponding read voltage levels R1-R7, to the selected WL and subsequently senses a corresponding BL current. In embodiments, the controller compares the BL current against a reference current to determine the threshold voltage. In embodiments, a BL pre-charge time or stabilization wait time is applied before substantially each sense operation to ensure that WL voltage has stabilized to the corresponding read voltage level and that the BL current is substantially stable.

To further illustrate, FIG. 4 schematically illustrates an example waveform 400 of the selected WL for a read operation of an XP according to the example of FIG. 3. A voltage of waveform 400 is schematically depicted vertically and a time of waveform 400 is schematically depicted horizontally. As noted above, to read the example XP, a controller or component of the memory device applies a series of read voltages, Rᵢ, corresponding to read voltage levels R1, R3, R5 and R7, to the selected WL. As noted above, in embodiments, a duration of a pre-charge time or stabilization wait time allows the WL voltage and BL current to stabilize shown before corresponding sense operations are performed. For example, in FIG. 4, a stabilization wait time for, e.g., read voltage level R3, is indicated at arrow 401followed by a sense operation performed at 403.

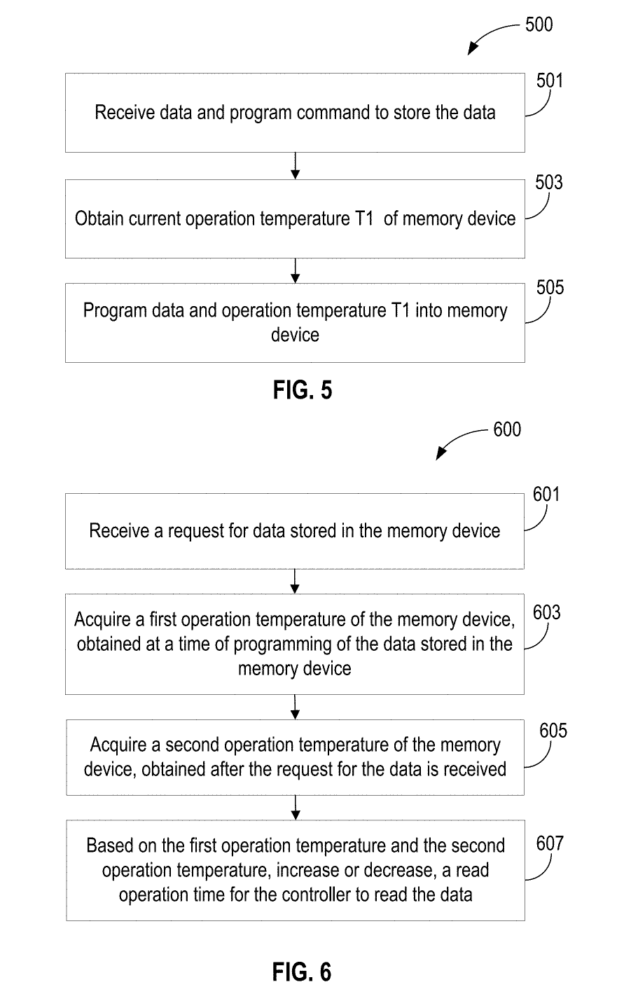

Accordingly, FIG. 5 is a flow diagram illustrating a process 500 that is performed by, e.g., the controller, to obtain and store a program operation temperature in connection with an adjustment of a read operation time, in accordance with various embodiments. In an embodiment, beginning at a block 501, the controller receives data to be stored and a program command to store the data in a memory device. In embodiments, the memory device is a non-volatile or flash memory device and as described above, memory cells of the memory device are programmed to at least one of a plurality of threshold voltage levels. In some embodiments, the controller receives data that includes a plurality of pages, such as, e.g., an LP, UP, and XP. After receiving the data at block 501, at a next block 503, the controller obtains a current program operation temperature T1 of the memory device. Note that in embodiments, the program operation temperature T1 is received by the controller from a temperature sensing circuit of the memory device. In embodiments, the controller includes a temperature extraction module to obtain the first operation temperature of the memory device after the data is received by the controller from a user. At a block 505, in embodiments, the controller stores or programs (writes) the data along with program operation temperature T1 into the memory device. In embodiments, program operation temperature T1 may be stored in one or more of the flag bytes of one or more of the stored pages of data.

FIG. 6 is a flow diagram illustrating a process 600 in connection with adjustment of the read operation time based on the stored program operation temperature of FIG. 5 in, e.g., an MLC NAND memory device, in accordance with various embodiments. In embodiments, the read operation time is a read operation time corresponding to a page of data. For example, beginning at block 601, the controller receives a request for data stored in the memory device. In embodiments, at a block 603, the controller acquires a program operation temperature T1 of the memory device, obtained at a time of programming of the data. In some examples, the controller acquires first operation temperature T1 by retrieving first operation temperature T1 from one or more flag bytes of one or more stored pages of data (e.g., see block 505). Next, at block 605, the controller acquires a read operation temperature or second temperature T2 of the memory device. In embodiments, the read operation temperature T2 is obtained after a controller performs a first sense operation out of a plurality of sense operations for reading a page of data (further discussed below). In embodiments, a temperature extraction module of the controller is to obtain the read operation temperature T2 from a temperature sensing circuit of the memory device. At block 607, in the embodiment, based on the first operation temperature and the second operation temperature, the controller may adjust the read operation time by increasing or decreasing a read operation time for a page of data.

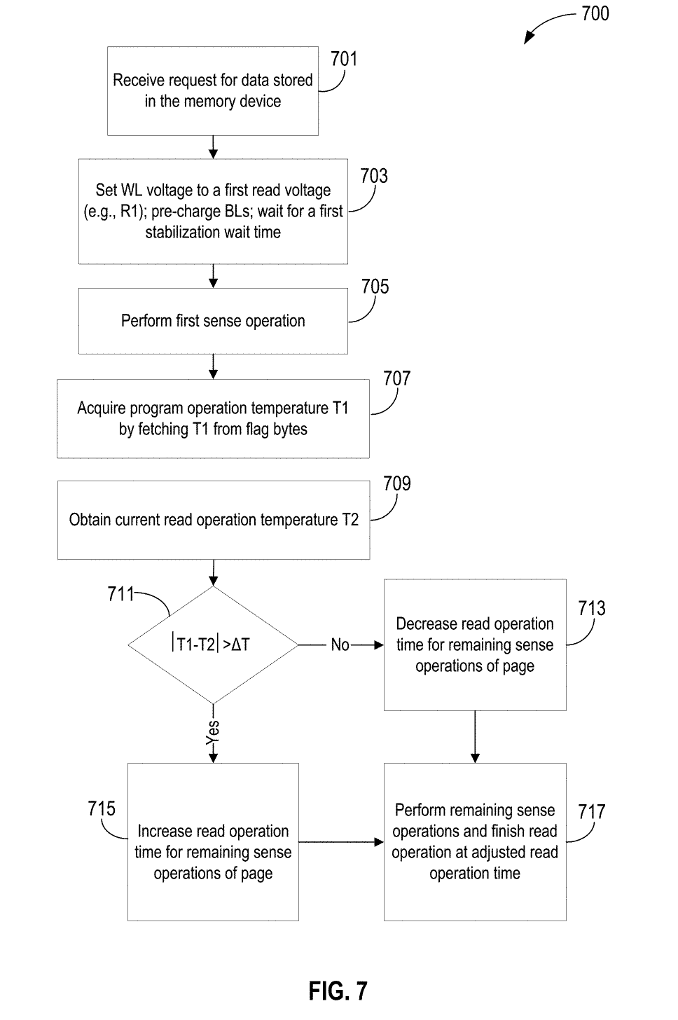

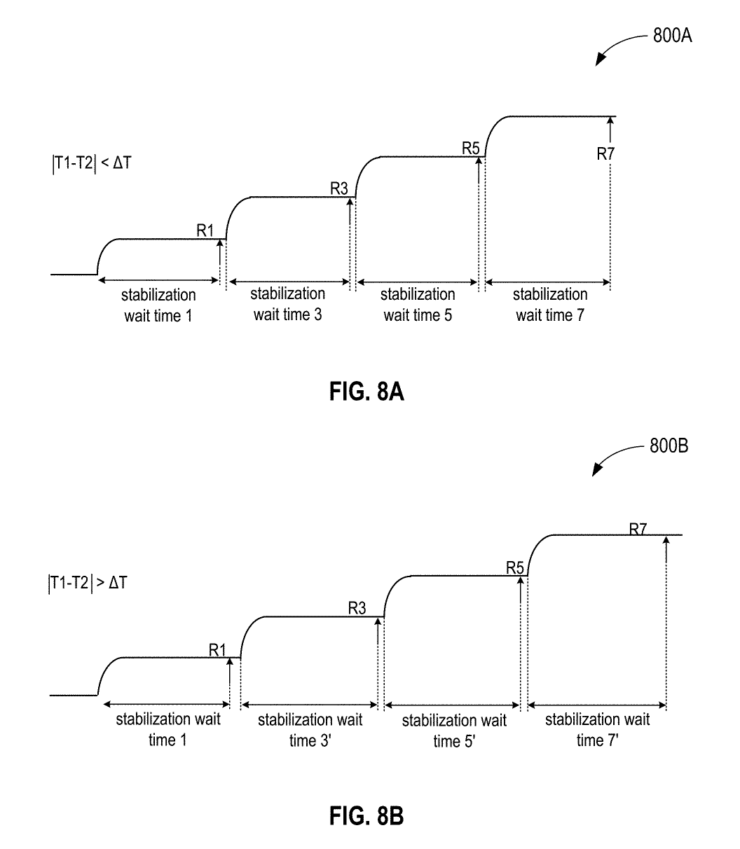

FIG. 7 is a process 700, which, in conjunction with FIGS. 8A and 8B, illustrates in further detail embodiments associated with process 600 of FIG. 6. FIGS. 8A and 8B schematically illustrate example waveforms 800A and 800B of a selected WL (“WL”) for read operations of the example XP, in accordance with various embodiments. In embodiments, at a first block 701, a controller of a memory device receives a request for data including a read command and an address for the data. In embodiments, the controller includes a read operation time adjustment module or circuitry operable by the controller to perform process 700 to adjust the read operation time by respectively increasing or decreasing a stabilization wait time prior to a sense operation for reading a page of data. In embodiments, the stabilization wait time includes a BL and WL stabilization wait time.

In embodiments, the controller performs a read operation that includes performance of more than one sense operation corresponding to a threshold voltage level of a memory cell, e.g., for reading data of an XP, where sense operations corresponding to read voltages R1, R3, R5 and R7 are to be performed. Thus, for example, at block 703, the controller sets the WL voltage to a first read voltage level, e.g., R1, pre-charges BLs, and waits for a first pre-charge time or stabilization wait time. Accordingly, after the stabilization wait time has passed, in embodiments, the controller or memory component performs a first sense operation at block 705, by sensing the BL current at first read voltage level R1. At a next block 707, in embodiments, the controller acquires program operation temperature T1 by fetching T1 from, e.g., flag bytes of the XP, as discussed in connection with FIG. 6.

Next, at block 709, in embodiments, the controller then obtains a current temperature or read operation temperature T2. In embodiments, read operation temperature T2 is a temperature sensed by a sensing circuit of the memory device. Next at decision block 711, the controller compares and/or analyzes program operation temperature T1 and read operation temperature T2. In embodiments, the controller compares a difference |T1−T2| to a threshold ΔT. Accordingly, in the embodiment shown, if |T1−T2|>ΔT is NO, the process flows to a block 713 and the controller decreases a read operation time for remaining read voltages for the current page being read, e.g., XP. In embodiments, the controller uses more “aggressive” stabilization wait times due to less stringent operating conditions associated with the memory device. In the alternative, for the embodiment, if the answer to |T1−T2|>ΔT, is YES, the process moves to a block 715. In embodiments, the controller increases a read operation time for remaining read voltage levels for a current page being read, e.g., XP. In embodiments, the controller will use a set of relatively more “conservative” stabilization wait times, due to more stringent or challenging operating conditions associated with the example memory device. In embodiments, from either block 713 or 715, process 700 moves to a block 717, where the controller will perform the remaining sense operations and finish the read operation for the current page at an adjusted read operation time.

FIGS. 8A and 8B are waveforms 800A and 800B illustrating the more “aggressive” stabilization times and more “conservative” stabilization times for read operations of the example page of data, e.g., XP, as discussed above. In FIGS. 8A and 8B, respective waveforms 800A and 800B representing voltage of a selected WL are schematically depicted vertically, and a time of each corresponding waveform is schematically depicted horizontally. In the embodiment, waveform 800A illustrates decreased stabilization wait times at stabilization wait time 3, stabilization wait time 5 and stabilization wait time 7, for remaining read voltage levels R3, R5, and R7. In contrast, waveform 800B illustrates increased stabilization wait times, e.g., stabilization wait time 3′, stabilization wait time 5′ and stabilization wait time 7′, for remaining read voltage levels to be applied for the XP. Note that in embodiments, stabilization wait time 1 is not adjusted in either FIG. 8A or 8B, i.e., increased or decreased, due to the controller obtaining read temperature operation time T2 after a sense operation is performed corresponding to read voltage level R1.

To further illustrate, note that in embodiments, according to, for example, the Gray code of FIG. 3, to read data of an LP, only one sense operation at read voltage level R4 is performed to read an LP bit. Thus, in embodiments, the controller does not perform an adjustment of a stabilization wait time for reading of the LP. In contrast, in embodiments, similar to the XP example above, to read data of an UP, a plurality of sense operations are performed. Thus, for example, the controller obtains program operation temperature T1 after performing a sense operation corresponding to read voltage level R2. In embodiments, the controller determines |T1−T2| and uses the difference to adjust a stabilization wait time for read voltage level R6. As discussed above in connection with FIG. 7, to read an XP, program operation temperature T1 is obtained after performing a sense operation corresponding to read voltage R1. Accordingly, stabilization wait times for read voltage levels R3, R5, and R7 are at least partially based on |T1−T2|, in the embodiment.

Although the above embodiment focuses on an example TLC NAND memory device, any suitable multi-level cell (MLC) memory device is contemplated. Note that, in various embodiments, according to other possible codes or Gray codes, reading data from an LP, UP or XP or additional higher order pages includes performance of sense operations corresponding to various subsets of read voltages. For example, in a quad-level cell (QLC) NAND memory device, a plurality of memory cells may include data from four pages, e.g., LP, UP, XP and TP. Accordingly, in embodiments, sense operations may correspond to read voltage levels ranging from R1 to R15. In some embodiments, the controller reads data of an LP by performing a read operation including a single sense operation corresponding to a read voltage R8 and does not adjust stabilization wait times for the LP page. To read data of an UP, however, the controller performs sense operations corresponding to read voltage levels R4 and R12, in embodiments. Thus, the controller obtains a read operation temperature after a first sense operation at read voltage level R4. Accordingly, the controller adjusts a stabilization wait time corresponding to read voltage R12 based on the read operation temperature and an acquired program operation temperature. In embodiments, when the controller reads data of an XP, it will perform sense operations corresponding to read voltage levels R2, R6, R10, and R14. Accordingly, in embodiments, after a first sense operation at read voltage level R2, the controller obtains a read operation temperature to adjust stabilization wait time corresponding to read voltages at R6, R10, and R14. Similarly, in embodiments, the controller reads data of a TP page by performing sense operations corresponding to read voltages R1, R3, R5, R7, R9, R11, R13 and R15. Accordingly, after performing a first sense operation at read voltage level R1, the controller obtains a read operation temperature from the memory device to adjust stabilization wait times for R3, R5, . . . , R15.

Accordingly, in embodiments, the controller obtains a read operation temperature after a first sense operation is performed corresponding to a first read voltage of a plurality of read voltage levels. In embodiments, the controller will base an adjustment of the stabilization wait times at least partially on a value of the read operation temperature for subsequent sense operations for a current page.

In embodiments, threshold or parameter ΔT is, for example, a prescribed value or other pre-determined value. According to various embodiments, the parameter may be set empirically based on a required read window budget (RWB) and at least partially on performance measurements of a population of non-volatile memory device components, e.g., NAND components. In embodiments, the parameters may be adjusted at a foundry or at another subsequent time. Note that in various embodiments, the controller may increase or decrease stabilization wait times based on any suitable function of program operation temperature T1 and read operation temperature T2. For example, in embodiments, the controller determines whether T1 and T2 are both in a temperature range [Ta, Tb], e.g., [30° C. to 70° C.]. In some embodiments, the controller or memory component applies an asymmetric temperature condition. For example, if T1>T2, i.e., data is programmed at a higher temperature than at which it is to be read, a first parameter ΔT1 is implemented, whereas if T1<T2, a second parameter ΔT2 is implemented.

Additionally, note that in the current examples, the controller obtains and uses a read operation temperature T2 obtained after a first stabilization wait time. In other embodiments, the read operation time T2 may be obtained at any suitable time during the read operation that provides a suitable temperature value for adjusting the read operation time.

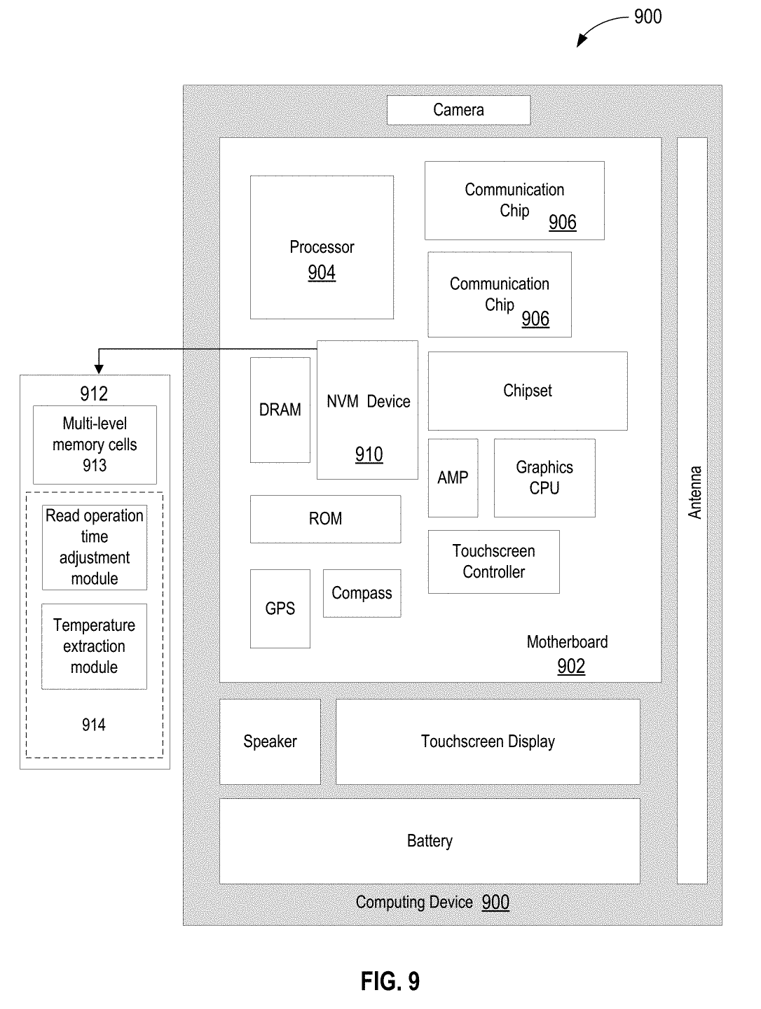

FIG. 9 illustrates a computing system including a computing device 900 that includes a memory device (e.g., a non-volatile memory device (NVM) 910) in accordance with various embodiments of the present disclosure. In embodiments, computing device 900 houses a board 902, such as, for example, a motherboard. The board 902 may include a number of components, including but not limited to a processor 904 and at least one communication chip 906. The processor 904 is physically and electrically coupled to the board 902. In some implementations, the at least one communication chip 906 is also physically and electrically coupled to the board 902. In further implementations, the communication chip 906 is part of the processor 904.

The NVM 910 may be packaged in an IC assembly (e.g., IC assembly 100 of FIG. 1) that includes the NVM 910 that performs a read operation time adjustment as described herein in accordance with some embodiments.

Accordingly, in some embodiments, the memory device is a NAND memory device 912, and includes, or is coupled to, a controller 914 to receive a request for data stored in the memory device. As shown, NAND memory device 912 includes a read operation time module and temperature extraction module (and/or circuitry) that are operable and/or included in controller 914 to perform operations in connection with a read operation time adjustment as described in connection with FIGS. 5-8B. Accordingly, in embodiments, controller 914 is to acquire a first operation temperature of the memory device, obtained at a time of programming of the data stored in the memory device; acquire a second operation temperature of the memory device, obtained after the request for the data stored in the memory device is received; and based on the first operation temperature and the second operation temperature, increase or decrease a read operation time for the controller to read the data. In embodiments, the memory device is a multi-level flash memory device including multi-level memory cells 913.

Depending on its applications, computing device 900 may include other components that may or may not be physically and electrically coupled to the board 902. These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 906 may enable wireless communications for the transfer of data to and from the computing device 900. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 906 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 900 may include a plurality of communication chips 906. For instance, a first communication chip 906 may be dedicated to shorter range wireless communications such as Wi-Fi and Bluetooth and a second communication chip 906 may be dedicated to longer range wireless communications such as GPS, EDGE, GPRS, CDMA, WiMAX, LTE, Ev-DO, and others.

The processor 904 of the computing device 900 includes an integrated circuit die packaged within the processor 904. In some implementations of the invention, the integrated circuit die of the processor includes one or more devices, such as MOS-FET transistors built in accordance with implementations of the invention. The term “processor” may refer to any device or portion of a device that processes electronic data from registers and/or memory to transform that electronic data into other electronic data that may be stored in registers and/or memory.

The communication chip 906 also includes an integrated circuit die, e.g., die described in connection with the above embodiments, packaged within the communication chip 906. In accordance with another implementation of the invention, the integrated circuit die of the communication chip includes one or more devices, such as MOS-FET transistors built in accordance with implementations of the invention.

In further implementations, another component housed within the computing device 900 may contain an integrated circuit die that includes one or more devices, such as MOS-FET transistors built in accordance with implementations of the invention.

In various implementations, the computing device 900 may be a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device 900 may be any other electronic device that processes data.

According to various embodiments, the present disclosure describes a number of examples.

Example 1 is an apparatus that includes a controller for a memory device, the controller to receive a request for data stored in the memory device; and a read operation time adjustment module operable by the controller to acquire a first operation temperature of the memory device, obtained at a time of programming of the data stored in the memory device; acquire a second operation temperature of the memory device, obtained after the request for the data stored in the memory device is received; and based at least partially on the first operation temperature and the second operation temperature, adjust a read operation time for the controller to read the data.

Example 2 is the apparatus of Example 1, wherein the memory device is a multi-level cell (MLC) non-volatile memory device and wherein memory cells of the memory device are programmed to at least one of a plurality of threshold voltage levels.

Example 3 the apparatus of Example 1, wherein the read operation time adjustment module is to adjust a read operation time by respectively increasing or decreasing a stabilization wait time prior to a sense operation for reading a page of data.

Example 4 is the apparatus of Example 3, wherein the stabilization wait time includes a bitline and wordline stabilization time.

Example 5 is the apparatus of Example 1, further comprising a temperature extraction module to obtain the first operation temperature of the memory device after data is received by the controller and prior to programming of the data into the memory device.

Example 6 the apparatus of Example 5, wherein the temperature extraction module is to obtain the second operation temperature of the memory device after a first sense operation of a plurality of sense operations is performed by the controller for reading a page of data.

Example 7 is the apparatus of Example 1, wherein the controller is to acquire the first operation temperature by retrieving the first operation temperature from a flag byte of one or more stored pages of data.

Example 8 is the apparatus of Example 1, wherein if a difference between the first operation temperature and the second operation temperature is less than a threshold, the read operation time is decreased.

Example 9 is the apparatus of any one of Examples 1-8, wherein if a difference between the first operation temperature and the second operation temperature is greater than a threshold, the read operation time is increased.

Example 10 is a method, comprising acquiring a first temperature of a memory device, obtained at a time of programming of data stored in the memory device; acquiring a second temperature of the memory device, obtained at a time of reading of the data stored in the memory device; and based at least in part on the first temperature and the second temperature, adjusting an operation time for reading the data stored in the memory device.

Example 11 is the method of Example 10, wherein the first temperature and the second temperature are first and second operation temperatures sensed by a sensing circuit of a multi-level flash memory.

Example 12 is the method of Example 10, wherein adjusting the operation time for reading the data includes increasing or decreasing a stabilization wait time prior to a sense operation performed during reading of the data.

Example 13 is the method of Example 12, wherein increasing or decreasing the stabilization wait time includes increasing a bitline and wordline stabilization time based on a difference between the first and the second temperature.

Example 14 is the method of Example 10, wherein the data includes three pages of data and the method further comprises storing the first temperature in a flag byte of one or more of the three pages of data.

Example 15 is the method of any one of Examples 10-14, wherein acquiring the first temperature of the memory device comprises retrieving the first temperature of the memory device stored in the flag byte of the one or more of the three pages of data.

Example 16 is the method of any one of Examples 10-14, further comprising receiving a read command for the data and wherein acquiring the second temperature of the memory device includes obtaining the second temperature after a first sense operation of a plurality of sense operations during a read operation of the data.

Example 17 may include an apparatus comprising means for performing the method of any one of Examples 10-14, or some other example herein.

Example 18 may include a computer-readable medium comprising instructions stored thereon, that in response to execution of the instructions cause an electronic device to perform the method of any one of Examples 10-14, or some other example herein.

Example 19 is a system, comprising: a memory device; a controller coupled to the memory device, the controller to receive a request for data stored in the memory device, wherein the controller is to acquire a first operation temperature of the memory device, obtained at a time of programming of the data stored in the memory device; acquire a second operation temperature of the memory device, obtained after the request for the data stored in the memory device is received; and based on the first operation temperature and the second operation temperature, increase or decrease a read operation time for the controller to read the data.

Example 20 is the system of Example 19, wherein the memory device comprises a multi-level flash memory device.

Example 21 is the system of Example 20, wherein the data includes a page of data and the controller is to increase or decrease the read operation time after obtaining the second operation temperature of the memory device after a first sense operation of a plurality of sense operations for reading the page of data.

Example 22 is the system of Example 21, wherein the controller is to increase or decrease the read operation time based at least in part on an increased or decreased bitline pre-charge wait time.

Example 23 is the system of Example 22, wherein the increased or decreased bitline pre-charge wait time is based at least in part on a temperature range of the first operation temperature and the second operation temperature.

Example 24 is the system of Example 22, wherein the increased or decreased bitline pre-charge wait time is based at least in part on an asymmetric temperature condition.

Example 25 is the system of Example 19, wherein the first operation temperature is a program operation temperature retrieved from a flag byte of a stored page of data.

Example 26 is the system of Example 19, wherein the memory device is a NAND flash memory device including a three-level-per-cell (TLC) or, in the alternative, a four-level-per-cell (QLC) NAND memory array.

Example 27 is the system of any one of Examples 19-26, further comprising a processor and a display coupled to the memory device and wherein the system comprises a mobile computing device.

Various embodiments may include any suitable combination of the above-described embodiments, including alternative (or) embodiments of embodiments that are described in conjunctive form (and) above (e.g., the “and” may be “and/or”). Furthermore, some embodiments may include one or more articles of manufacture (e.g., non-transitory computer-readable media) having instructions, stored thereon, that when executed result in actions of any of the above-described embodiments. Moreover, some embodiments may include apparatuses or systems having any suitable means for carrying out the various operations of the above-described embodiments.

The above description of illustrated implementations, including what is described in the Abstract, is not intended to be exhaustive or to limit the embodiments of the present disclosure to the precise forms disclosed. While specific implementations and examples are described herein for illustrative purposes, various equivalent modifications are possible within the scope of the present disclosure, as those skilled in the relevant art will recognize.

These modifications may be made to embodiments of the present disclosure in light of the above detailed description. The terms used in the following claims should not be construed to limit various embodiments of the present disclosure to specific implementations disclosed in the specification and the claims. Rather, the scope is to be determined entirely by the following claims, which are to be construed in accordance with established doctrines of claim interpretation.

What is claimed is:

1. An apparatus, comprising:
a controller for a memory device, the controller to receive a request for data stored in the memory device; and
a read operation time adjustment module operable by the controller to:
acquire a first operation temperature of the memory device, obtained at a time of programming of the data stored in the memory device;
acquire a second operation temperature of the memory device, obtained after the request for the data stored in the memory device is received; and
based at least partially on the first operation temperature and the second operation temperature, adjust a read operation time for the controller to read the data.

2. The apparatus of claim 1, wherein the memory device is a multi-level cell (MLC) non-volatile memory device and wherein memory cells of the memory device are programmed to at least one of a plurality of threshold voltage levels.

3. The apparatus of claim 1, wherein the read operation time adjustment module is to adjust a read operation time by respectively increasing or decreasing a stabilization wait time prior to a sense operation for reading a page of data.

4. The apparatus of claim 3, wherein the stabilization wait time includes a bitline and wordline stabilization time.

5. The apparatus of claim 1, further comprising a temperature extraction module to obtain the first operation temperature of the memory device after data is received by the controller and prior to programming of the data into the memory device.

6. The apparatus of claim 5, wherein the temperature extraction module is to obtain the second operation temperature of the memory device after a first sense operation of a plurality of sense operations is performed by the controller for reading a page of data.

7. The apparatus of claim 1, wherein the controller is to acquire the first operation temperature by retrieving the first operation temperature from a flag byte of one or more stored pages of data.

8. The apparatus of claim 1, wherein if a difference between the first operation temperature and the second operation temperature is less than a threshold, the read operation time is decreased.

9. The apparatus of claim 1, wherein if a difference between the first operation temperature and the second operation temperature is greater than a threshold, the read operation time is increased.

10. A method, comprising:
acquiring a first temperature of a memory device, obtained at a time of programming of data stored in the memory device;
acquiring a second temperature of the memory device, obtained at a time of reading of the data stored in the memory device; and
based at least in part on the first temperature and the second temperature, adjusting an operation time for reading the data stored in the memory device.

11. The method of claim 10, wherein the first temperature and the second temperature are first and second operation temperatures sensed by a sensing circuit of a multi-level flash memory.

12. The method of claim 10, wherein adjusting the operation time for reading the data includes increasing or decreasing a stabilization wait time prior to a sense operation performed during reading of the data.

13. The method of claim 12, wherein increasing or decreasing the stabilization wait time includes increasing a bitline and wordline stabilization time based on a difference between the first and the second temperature.

14. The method of claim 10, wherein the data includes three pages of data and the method further comprises storing the first temperature in a flag byte of one or more of the three pages of data.

15. The method of claim 14, wherein acquiring the first temperature of the memory device comprises retrieving the first temperature of the memory device stored in the flag byte of the one or more of the three pages of data.

16. The method of claim 10, further comprising receiving a read command for the data and wherein acquiring the second temperature of the memory device includes obtaining the second temperature after a first sense operation of a plurality of sense operations during a read operation of the data.

17. A system, comprising:
a memory device;
a controller coupled to the memory device, the controller to receive a request for data stored in the memory device, wherein the controller is to:
acquire a first operation temperature of the memory device, obtained at a time of programming of the data stored in the memory device;
acquire a second operation temperature of the memory device, obtained after the request for the data stored in the memory device is received; and
based on the first operation temperature and the second operation temperature, increase or decrease a read operation time for the controller to read the data.

18. The system of claim 17, wherein the memory device comprises a multi-level flash memory device.

19. The system of claim 18, wherein the data includes a page of data and the controller is to increase or decrease the read operation time after obtaining the second operation temperature of the memory device after a first sense operation of a plurality of sense operations for reading the page of data.

20. The system of claim 18, further comprising a processor and a display coupled to the memory device and wherein the system comprises a mobile computing device.
